(19) United States
(12) Patent Application Publication
(10) Pub. No.: US 2024/0427226 A1
(43) Pub. Date: Dec. 26, 2024

(54) REFLECTIVE MASK BLANK, REFLECTIVE MASK, AND MANUFACTURING METHOD THEREFOR

(71) Applicant: AGC Inc., Tokyo (JP)

(72) Inventors: Takeshi Okato, Tokyo (JP); Daijiro Akagi, Tokyo (JP); Takeshi Isogawa, Tokyo (JP)

(73) Assignee: AGC Inc., Tokyo (JP)

(21) Appl. No.: 18/822,677

(22) Filed: Sep. 3, 2024

Related U.S. Application Data
(63) Continuation of application No. PCT/JP2023/008185, filed on Mar. 3, 2023.

(30) Foreign Application Priority Data
Mar. 8, 2022 (JP) 2022-035465

(51) Int. Cl. G03F 1/24; G03F 1/52; G03F 1/58; G03F 1/80

(52) U.S. Cl. CPC G03F 1/24; G03F 1/52; G03F 1/58; G03F 1/80

(57) ABSTRACT

A reflective mask blank for EUV lithography, the reflective mask blank including: a substrate; a multilayer reflective film configured to reflect EUV light; and an absorption layer configured to absorb EUV light, in this order from a substrate side, in which the absorption layer includes a first absorption film and a second absorption film in this order from the substrate side, the absorption layer has a refractive index for EUV light having a wavelength of 13.5 nm of 0.95 or less, and the first absorption film is more easily chemically dry etched than the second absorption film.

### CROSS-REFERENCE TO RELATED APPLICATIONS

This is a bypass continuation of International Patent Application No. PCT/JP2023/008185, filed on Mar. 3, 2023, which claims priority to Japanese Patent Application No. 2022-035465, filed on Mar. 8, 2022. The contents of these applications are hereby incorporated by reference in their entireties.

### TECHNICAL FIELD

The present invention relates to a reflective mask blank for use in extreme ultraviolet (EUV) lithography in semiconductor production or the like, a reflective mask including the reflective mask blank, and a method for manufacturing the reflective mask.

### BACKGROUND ART

A reflective mask used for EUV lithography is provided with a mask pattern by an absorption layer configured to absorb EUV light on a multilayer reflective film configured to reflect EUV light having a short wavelength of about 13.5 nm. In the reflective mask, in the case where the absorption layer is thick, a dimension error of a transfer pattern is likely to occur due to shadowing, that is, the EUV light incident obliquely and reflected light thereof being blocked.

For this reason, a phase shift mask which absorbs EUV light and improves contrast of a transfer pattern by an absorption layer which reflects (preferably inverted) light in a different phase from reflected light from a multilayer reflective film is being adopted.

In order to increase a phase difference between the reflected light from the multilayer reflective film and the reflected light from the absorption layer, it is desirable that a refractive index of the absorption layer be low. In addition, it is desirable that the absorption layer can be controlled to have any reflectance.

For example, Patent Literature 1 describes that a phase shift mask having selectivity with wide reflectance of an absorption layer containing tantalum (Ta) and niobium (Nb) is obtained by changing a composition ratio of Ta and Nb in the absorption layer.

### CITATION LIST

### Patent Literature

Patent Literature 1: JP2021-174003A

### SUMMARY OF INVENTION

However, the absorption layer described in Patent Literature 1 is an alloy, requiring control of a composition ratio of the alloy, and the refractive index is relatively large, requiring formation of a film by the alloy with a thickness of about 60 nm.

On the other hand, examples of a material having a low refractive index include ruthenium (Ru), and in order to change the reflectance, it is considered to alloy with platinum (Pt), iridium (Ir), or the like having a larger absorption coefficient of EUV light. However, Pt or Ir is a difficult-to-etch material, and an absorption layer formed using Pt or Ir is difficult to be etched by chemical dry etching, which is plasma etching generally applied at the time of mask pattern formation, making it difficult to form a fine mask pattern required for a reflective mask for EUV lithography.

The present invention has been made in view of such a situation, and an object thereof is to provide a reflective mask blank for EUV lithography capable of efficiently and accurately forming a mask pattern by dry etching even when a difficult-to-etch material is used for an absorption layer, a reflective mask including the reflective mask blank, and a method for manufacturing the reflective mask.

The present invention is based on the finding that an absorption layer of a reflective mask blank for EUV lithography includes a film made of a difficult-to-etch material and a film made of an easy-to-etch material which is easily chemically dry etched, so that the absorption layer can be etched efficiently and accurately.

The present invention provides the following solutions.

[1] A reflective mask blank for EUV lithography, the reflective mask blank including:
a substrate;
a multilayer reflective film configured to reflect EUV light; and
an absorption layer configured to absorb EUV light, in this order from a substrate side, in which
the absorption layer comprises a first absorption film and a second absorption film in this order from the substrate side,
the absorption layer has a refractive index for EUV light having a wavelength of 13.5 nm of 0.95 or less, and
the first absorption film is more easily chemically dry etched than the second absorption film.

[2] The reflective mask blank according to [1], in which the second absorption film includes one or more metal elements selected from Group 9 elements to Group 13 elements.

[3] The reflective mask blank according to [2], in which the one or more metal elements in the second absorption film are selected from a group consisting of cobalt (Co), rhodium (Rh), iridium (Ir), nickel (Ni), palladium (Pd), platinum (Pt), copper (Cu), silver (Ag), gold (Au), cadmium (Cd), and indium (In).

[4] The reflective mask blank according to [1], in which the first absorption film includes one or more metal elements selected from Group 4 elements to Group 8 elements and Group 14 elements.

[5] The reflective mask blank according to [4], in which the one or more metal elements in the first absorption film are selected from a group consisting of titanium (Ti), niobium (Nb), tantalum (Ta), chromium (Cr), molybdenum (Mo), tungsten (W), rhenium (Re), iron (Fe), ruthenium (Ru), osmium (Os), silicon (Si), germanium (Ge), and tin (Sn).

[6] The reflective mask blank according to [1], in which the absorption layer has a total thickness of 60 nm or less.

[7] The reflective mask blank according to [1], in which a phase difference between a reflected light from a surface of the multilayer reflective film and a reflected light from a surface of the absorption layer is 150° to 270° with respect to an incident light of EUV light having a wavelength of 13.5 nm at an incident angle of 6°.

[8] The reflective mask blank according to [1], further including an antireflection film configured to prevent reflection of DUV light having a wavelength of 190 nm to 260 nm on or above the absorption layer.

[9] A reflective mask including:
the reflective mask blank according to any of [1] to [8]; and
a mask pattern formed on the absorption layer.

A method for manufacturing the reflective mask according to [9], the method including:
forming the mask pattern, in which
the formation of the mask pattern is performed by subjecting the absorption layer of the reflective mask blank to a sputtering etching treatment and then to a chemical dry etching treatment.

According to the present invention, it is possible to provide a reflective mask blank for EUV lithography capable of efficiently and accurately forming a mask pattern by dry etching even when a difficult-to-etch material is used for an absorption layer, a reflective mask including the reflective mask blank, and a method for manufacturing the reflective mask.

### BRIEF DESCRIPTION OF DRAWINGS

FIG. 1 is a schematic cross-sectional view schematically illustrating a reflective mask blank according to an embodiment of the present invention.

FIGS. 2A to 2C are schematic cross-sectional views illustrating an etching process of the reflective mask blank according to the embodiment of the present invention.

### DESCRIPTION OF EMBODIMENTS

Definitions and meanings of terms and notations in the present description are as follows.

Expressions “on or above the substrate”, “on or above the layer”, and “on or above the film” (hereinafter, abbreviated as “on or above the film or the like”) means not only the case of being in contact with an upper surface of the film or the like, but also the case of being not in contact with the upper surface of the film or the like. For example, an expression of “the film B on or above the film A” means that the film A and the film B may be in contact with each other, and another film or the like may be interposed between the film A and the film B. An expression “above” as used herein does not necessarily mean a high position in a vertical direction, and indicates a relative positional relation.

The refractive index is a value obtained by weight-averaging in consideration of the thickness based on the refractive index of each film.

An expression “sputter etching” is physical etching by accelerating ions, neutral particles, and the like generated from an etching gas by discharge plasma or the like and causing the ions, the neutral particles, and the like to collide with a material to be etched so as to repel particles of the material to be etched (sputtering), and refers to etching not mainly involving a chemical reaction. On the other hand, an expression “chemical dry etching” is chemical etching mainly in which an etching gas causes a chemical reaction on a surface of a material to be etched, generating a reaction product with the material to be etched, and is distinguished from physical etching in that a reaction product which is easily volatilized and detached by a chemical reaction is generated although a sputter-assisted action by ions or the like may be involved. It can be said that the reaction product is easily volatilized and detached using a boiling point as an indication, for example, when the boiling point is 400° C. or lower. The boiling point is a value at a constant pressure (1 atm).

An expression “difficult-to-etch material” refers to a material that is relatively less likely to be etched by chemical dry etching than other materials. Other materials to be compared, that is, materials that are easily etched by chemical dry etching, are referred to as “easy-to-etch materials”.

The thickness of the formed film or the like is a value measured by a transmission electron microscope or X-ray Reflectometry.

### [Reflective Mask Blank]

Hereinafter, an embodiment of the present invention will be described with reference to the drawings.

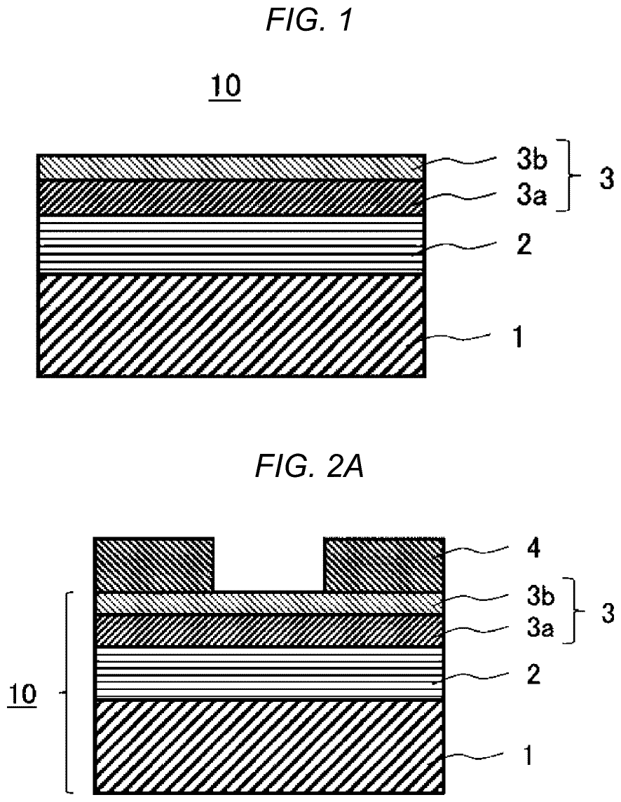

FIG. 1 schematically illustrates a cross section of a reflective mask blank according to the present embodiment. In a reflective mask blank 10 illustrated in FIG. 1, a multilayer reflective film 2 configured to reflect EUV light and an absorption layer 3 configured to absorb EUV light are laminated on or above a substrate 1 in this order from a substrate 1 side.

In general, a protective layer (also referred to as a cap layer) (not illustrated) for protecting the multilayer reflective film 2 from etching at the time of forming a mask pattern is formed between the multilayer reflective film 2 and the absorption layer 3. Further, an antireflection film (not illustrated) for facilitating pattern defect inspection after mask processing may be formed on or above the absorption layer 3.

### (Substrate)

From the viewpoint of preventing distortion of a transfer pattern due to heat during EUV exposure, the substrate 1 preferably has a low thermal expansion coefficient at 20° C., preferably 0±0.05×10⁻⁷/° C., and more preferably 0±0.03×10⁻⁷/° C. In addition, the substrate 1 preferably has excellent smoothness, high total indicated reading, and excellent resistance (chemical resistance) to a cleaning liquid used in a manufacturing process of a reflective mask.

Examples of a material of the substrate 1 include a SiO₂—TiO₂ glass and a multi-component glass ceramics, and a crystallized glass from which β-quartz solid solution is precipitated, a quartz glass, silicon, and metals can also be used.

The substrate 1 is preferably smooth from the viewpoint of performing pattern transfer with high reflectance and high accuracy, and the surface roughness (RMS) thereof is preferably 0.15 nm or less, and more preferably 0.10 nm or less. From the same viewpoint, the total indicated reading (TIR) thereof is preferably 100 nm or less, more preferably 50 nm or less, and further preferably 30 nm or less.

The substrate 1 preferably has high rigidity from the viewpoint of preventing deformation due to stress of a film or the like laminated thereon. Specifically, the Young's modulus is preferably 65 GPa or more.

### (Multilayer Reflective Film)

From the viewpoint of increasing the reflectance of EUV light, the multilayer reflective film 2 preferably has a configuration in which a plurality of layers containing elements having different refractive indices as main components are periodically laminated. In general, the multilayer reflective film 2 has a structure in which a set of one high refractive index layer and one low refractive index layer is set as one period, and lamination is performed for about 40 periods to 60 periods.

As the high refractive index layer/low refractive index layer, an Mo/Si multilayer reflective film is generally used, but the high refractive index layer/low refractive index layer is not limited thereto, examples thereof include an Ru/Si multilayer reflective film, an Mo/Be multilayer reflective film, an Mo compound/Si compound multilayer reflective film, an Si/Mo/Ru multilayer reflective film, an Si/Mo/Ru/Mo multilayer reflective film, and an Si/Ru/Mo/Ru multilayer reflective film.

The multilayer reflective film 2 has a reflectance of incident light of EUV light having a wavelength of about 13.5 nm at an incident angle of 6° of preferably 60% or more, and more preferably 65% or more.

A thickness of each film constituting the multilayer reflective film 2 and a repetition period of lamination are appropriately set according to the film material, the desired reflectance of EUV light, and the like.

The multilayer reflective film 2 can be formed by forming each of the constituent films to have a desired thickness using a known film forming method such as magnetron sputtering or ion beam sputtering.

For example, when an Mo/Si multilayer reflective film is formed by ion beam sputtering, an Si film is first formed to have a thickness of 4.5 nm using an Si target, and an Mo film is then formed to have a thickness of 2.3 nm using an Mo target, at an ion acceleration voltage of 300 V to 1,500 V and a film formation rate of 0.030 nm/sec to 0.300 nm/sec using an argon (Ar) gas (gas pressure of 1.3× 10⁻² Pa to 2.7×10⁻² Pa) as a sputtering gas. The Mo/Si multilayer reflective film can be formed by repeatedly laminating the Mo film/Si film for 30 cycles to 60 cycles with the above as one cycle.

A protective layer (not illustrated) may be formed on the uppermost surface of the multilayer reflective film 2. The protective layer is provided for the purpose of preventing the multilayer reflective film 2 from being oxidized at the time of EUV exposure and the reflectance of EUV light being reduced. In addition, the protective layer also plays a role of protecting the multilayer reflective film 2 from dry etching during mask pattern formation. Specific examples of the protective layer include an Si film having a thickness of about 11 nm±2 nm, an Ru film having a thickness of 1 nm to 5 nm, an Rh film having a thickness of 1 nm to 5 nm, and an SiO₂ film having a thickness of 1 nm to 5 nm.

Further, a buffer layer (not illustrated) for protecting the multilayer reflective film 2 at the time of dry etching or defect repair may be formed between the protective layer and the absorption layer 3. Constituent materials of the buffer layer are not particularly limited, and examples thereof include materials containing SiO₂, Cr, Ta, and the like as main components.

### (Protective Layer)

The protective layer included in the reflective mask blank according to the present invention is provided for the purpose of protecting the multilayer reflective film so that the multilayer reflective film is not damaged by an etching process (usually, dry etching process) at the time of forming a pattern on the absorption layer by the etching process.

Examples of a material that can implement the above purpose include a material containing at least one element selected from the group consisting of Ru and Rh. That is, the protective layer preferably contains at least one element selected from the group consisting of Ru and Rh.

More specifically, examples of the material include an Ru metal simple substance, an Ru alloy containing Ru and one or more metals selected from the group consisting of Si, Ti, Nb, Mo, Rh, and Zr, an Rh metal simple substance, an Rh alloy containing Rh and one or more metals selected from the group consisting of Si, Ti, Nb, Mo, Ru, Ta, and Zr, and an Rh-based material such as an Rh-containing nitride containing the Rh alloy and N, and an Rh-containing oxynitride containing the Rh alloy, N, and O.

In addition, examples of the material that can implement the above purpose include a nitride containing N as well as Al and these metals, and Al₂O₃.

Among them, the Ru metal simple substance, the Ru alloy, the Rh metal simple substance, or the Rh alloy is preferable as the material that can implement the above purpose. The Ru alloy is preferably an Ru—Si alloy or an Ru—Rh alloy, and the Rh alloy is preferably an Rh—Si alloy or an Rh—Ru alloy.

A film thickness of the protective layer is not particularly limited as long as the function as the protective layer can be ensured. From the viewpoint of maintaining the reflectance of EUV light reflected by the multilayer reflective film, the film thickness of the protective layer is preferably 1 nm to 10 nm, more preferably 1.5 nm to 6 nm, and further preferably 2 nm to 5 nm.

It is also preferable that the material of the protective layer be the Ru metal simple substance, the Ru alloy, the Rh metal simple substance, or the Rh alloy, and the film thickness of the protective layer be the above preferable film thickness.

The protective layer may be a film composed of a single layer or a multilayer film composed of a plurality of layers. When the protective layer is a multilayer film, each layer constituting the multilayer film is preferably made of the above-described preferable material. In addition, when the protective film is a multilayer film, a total film thickness of the multilayer film is preferably the film thickness of the protective layer within the above-described preferable range.

The protective layer can be formed by a known film forming method such as magnetron sputtering and ion beam sputtering. In the case where an Ru film is formed by magnetron sputtering, it is preferable to perform film formation by using an Ru target as a target and an Ar gas as a sputtering gas.

### (Absorption Layer)

In the absorption layer 3, a first absorption film 3a and a second absorption film 3b are laminated in this order from the substrate 1 side.

The first absorption film 3a is more easily chemically dry etched than the second absorption film 3b. That is, the first absorption film 3a is made of an easy-to-etch material, and the second absorption film 3b is made of a difficult-to-etch material.

For example, Pt, Ir, or the like has a large absorption coefficient of EUV light, but is a difficult-to-etch material, and thus is preferably etched by sputter etching. However, in the sputter etching, it is difficult to control the etching with high accuracy, and the absorption layer made of a difficult-to-etch material may not be sufficiently etched, or an underlying layer (for example, multilayer reflective film) may be damaged, which may significantly reduce the yield of the reflective mask.

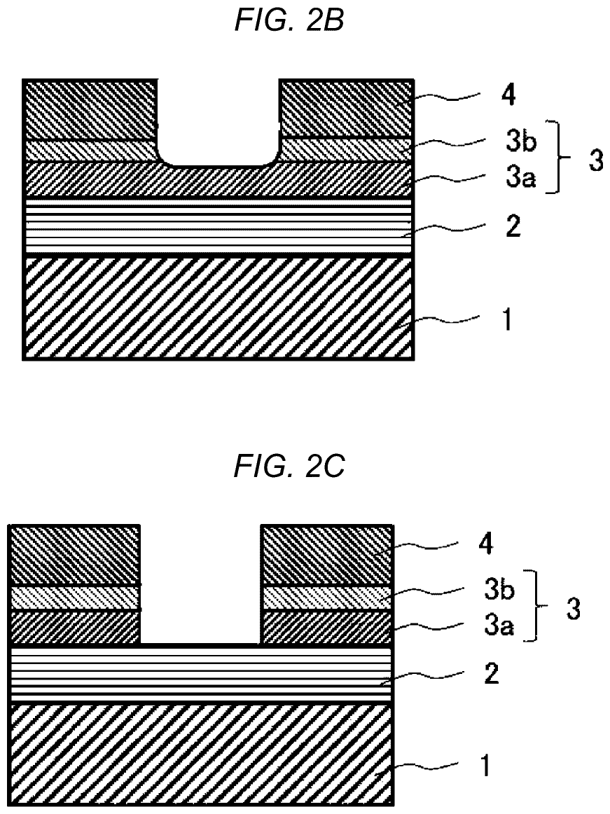

In contrast, in the present embodiment, the absorption layer 3 has a double layer structure of the first absorption film 3a and the second absorption film 3b, as illustrated in FIG. 1. With such a configuration of the absorption layer 3, damage to the multilayer reflective film 2 is suppressed through the following etching process (see FIGS. 2A to 2C), and a reflective mask free of surface roughness and residues can be efficiently and accurately manufactured.

FIGS. 2A to 2C schematically illustrate an etching process of the reflective mask blank 10 according to the present embodiment.

A resist pattern 4 is formed in advance on the absorption layer 3 of the reflective mask blank 10 (FIG. 2A) and is subjected to a sputter etching treatment, so that the absorption layer 3 at an opening of the resist pattern 4 is etched (FIG. 2B). In the sputter etching treatment, the second absorption film 3b at the opening of the resist pattern 4 is etched as much as possible without etching the entire absorption layer 3 by the thickness thereof, and etching is performed until the first absorption film 3a remains so that the multilayer reflective film 2 is not exposed.

Next, overetching is performed to the first absorption film 3a by a chemical dry etching treatment to completely etch the absorption layer 3 (FIG. 2C). The first absorption film 3a is made of an easy-to-etch material, and thus can be etched by the chemical dry etching treatment without causing surface roughness or residues of the multilayer reflective film 2.

The easy-to-etch material constituting the first absorption film 3a is preferably a material which has a low boiling point of a reaction product (for example, chloride, oxide, or fluoride) with a reactive etching gas (for example, chlorine, oxygen, or tetrafluoro methane) used in chemical dry etching and is easily volatilized.

As the easy-to-etch material, a material containing one or more metal elements selected from Group 4 elements to Group 8 elements and Group 14 elements is preferable. Specifically, the metal element is preferably one or more selected from titanium (Ti), niobium (Nb), tantalum (Ta), chromium (Cr), molybdenum (Mo), tungsten (W), rhenium (Re), iron (Fe), ruthenium (Ru), osmium (Os), silicon (Si), germanium (Ge), and tin (Sn). These metal elements are preferable because the reaction product thereof is easily volatilized. The metal element may be used alone or in combination of two or more.

The easy-to-etch material may be a simple substance of a metal element or a compound (including, for example, oxygen (O), nitrogen (N), carbon (C), boron (B), or hydrogen (H)). From the viewpoint of ease of processing and chemical resistance of the first absorption film 3a, the refractive index of EUV light, and the like, a material containing Ru, Ta, or Cr as a main component is more preferable. For example, Ru is likely to be chemically dry etched by oxygen plasma because an oxide thereof is likely to volatilize (for example, RuO₄: boiling point of 40° C.). In addition, Ta is easily chemically dry etched by chlorine-based or fluorine-based plasma because a chloride or a fluoride thereof is easily volatilized (for example, TaCl₅: boiling point of 239° C., TaF₄: boiling point of 230° C.). In addition, Cr is easily chemically dry etched by chlorine-based or fluorine-based plasma because an oxychloride or an oxyfluoride thereof is easily volatilized (for example, CrO₂Cl₂: boiling point of 117° C., CrO₂F₂: boiling point of 30° C.).

The difficult-to-etch material constituting the second absorption film 3b is preferably a material that is easily sputter etched, that is, a material having a high sputtering rate (probability value at which atoms fly out from material surface when incident ions or the like collide). The material having a high sputtering rate depends on energy and type of incident ions, and examples thereof include Al, In, Cr, Co, Ni, Cu, Ge, Ru, Rh, Pd, Ag, Sn, Ir, Pt, Au, Pb, and Cd.

The difficult-to-etch material preferably contains one or more metal elements selected from Group 9 elements to Group 13 elements. Specifically, the metal element is preferably one or more selected from cobalt (Co), rhodium (Rh), iridium (Ir), nickel (Ni), palladium (Pd), platinum (Pt), copper (Cu), silver (Ag), gold (Au), cadmium (Cd), and indium (In). The metal element may be used alone or in combination of two or more.

The difficult-to-etch material may be a simple substance of a metal element or a compound (including, for example, O, N, C, B, or H). From the viewpoint of ease of processing and chemical resistance of the second absorption film 3b, the refractive index of EUV light, the absorption coefficient, and the like, a material containing Pt or Ir as a main component is more preferable. For example, Pt is difficult to be chemically dry etched by chlorine plasma because a chloride thereof is hardly volatilized, and it is considered that etching is performed by scattering Pt or solid particles of which a part is platinum chloride by sputtering etching.

The first absorption film 3a and the second absorption film 3b can be formed by forming each of the constituent films to have a desired thickness using a known film forming method such as magnetron sputtering or ion beam sputtering.

Each of the first absorption film 3a and the second absorption film 3b may include a plurality of layers, but preferably includes one layer from the viewpoint of controlling the refractive index of the absorption layer 3, manufacturing efficiency of the reflective mask blank, and the like.

Preferable specific examples of the second absorption film 3b/first absorption film 3a include a Pt film/Ru film, an Ir film/Ru film, a Pt film/Ta film, a Pt film/Ta₂O₅ film, an Ir film/Cr film, and an Ir film/Ta₂O₅ film.

The refractive index of the absorption layer 3 for EUV light having a wavelength of 13.5 nm is 0.95 or less, preferably 0.94 or less, and more preferably 0.93 or less.

When the refractive index is within the above range, effects as a phase shift mask can be easily obtained that the reflected light from the multilayer reflective film 2 can be easily controlled at any reflectance and the contrast of the transfer pattern is good.

With the absorption layer as described above, the total thickness of the absorption layer 3 is 60 nm or less, and the effect as a phase shift mask can be exhibited. The total thickness of the absorption layer 3 is preferably thin, and is preferably 60 nm or less, more preferably 50 nm or less, and further preferably 40 nm or less, from the viewpoint of the efficiency of film formation and the etching of the absorption layer 3.

In order to sufficiently exhibit the effect as the phase shift mask, a phase difference between a reflected light from the surface of the multilayer reflective film 2 and a reflected light from the surface of the absorption layer 3 is preferably 150° to 270°, more preferably 160° to 255°, and further preferably 170° to 240° with respect to the incident light of EUV light having a wavelength of 13.5 nm at an incident angle of 6°. When the phase difference is within the above range, it is easy to obtain an effect of improving the accuracy by improving the contrast of the transfer pattern due to cancellation of the reflected light from the surface of the multilayer reflective film 2 and the reflected light from the surface of the absorption layer 3.

Even when the total thickness of the absorption layer 3 according to the present embodiment is as thin as 60 nm or less as described above, the reflectance can be freely adjusted without shifting the phase difference by changing a film thickness ratio of the first absorption film 3a and the second absorption film 3b without changing the total thickness, which is advantageous in designing the phase shift mask.

For example, Table 1 shows results of calculating, by optical simulation, the phase difference between the reflected light from the multilayer reflective film 2 and the reflected light from the absorption layer 3 of EUV light (wavelength of 13.5 nm and incident angle of 6°), the relative reflectance (reflected light from absorption layer 3/reflected light from multilayer reflective film 2), and the refractive index when the first absorption film 3a/second absorption film 3b is the Ru film/Pt film and each film thickness is changed in the reflective mask blank according to the present embodiment.

In addition, for example, Tables 2 and 3 respectively show results calculated in the same manner when the first absorption film/second absorption film is the Ru film/Ir film and when the first absorption film/second absorption film is the Ta film/Pt film.

Regarding optical constants used for the calculation, the refractive index is Ta: 0.957, Pt: 0.891, Ir: 0.905, and Ru: 0.886, and the absorption coefficient is Ta: 0.0343, Pt: 0.0600, Ir: 0.0433, and Ru: 0.0170. In the columns of the absorption layer in Tables 1 to 3, the absorption film (1) refers to the first absorption film, and the absorption film (2) refers to the second absorption film.

TABLE 1

| Absorption layer [nm] | | | | | |
|---|---|---|---|---|---|
| Total | Absorption | Absorption | Phase | Relative | |
| thick- | film (1) | film (2) | difference | reflectance | Refractive |
| ness | Ru | Pt | [°] | [%] | index |
| 34 | 10 | 24 | 221 | 2.4 | 0.889 |
| 34 | 11 | 23 | 222 | 2.7 | 0.889 |
| 34 | 12 | 22 | 223 | 2.8 | 0.889 |
| 34 | 13 | 21 | 223 | 2.8 | 0.889 |
| 34 | 14 | 20 | 222 | 2.9 | 0.889 |
| 34 | 15 | 19 | 219 | 3.2 | 0.889 |
| 34 | 16 | 18 | 218 | 4.0 | 0.888 |
| 34 | 17 | 17 | 218 | 5.0 | 0.888 |
| 34 | 18 | 16 | 219 | 5.9 | 0.888 |
| 34 | 19 | 15 | 221 | 6.3 | 0.888 |
| 34 | 20 | 14 | 221 | 6.3 | 0.888 |
| 34 | 21 | 13 | 221 | 6.2 | 0.888 |
| 34 | 22 | 12 | 219 | 6.6 | 0.888 |
| 34 | 23 | 11 | 217 | 7.7 | 0.888 |
| 34 | 24 | 10 | 216 | 9.5 | 0.887 |
| 34 | 25 | 9 | 217 | 11.5 | 0.887 |
| 34 | 26 | 8 | 219 | 13.0 | 0.887 |
| 34 | 27 | 7 | 221 | 13.5 | 0.887 |
| 34 | 28 | 6 | 221 | 13.2 | 0.887 |
| 34 | 29 | 5 | 220 | 13.2 | 0.887 |
| 34 | 30 | 4 | 217 | 14.4 | 0.887 |
| 34 | 31 | 3 | 216 | 17.2 | 0.886 |
| 34 | 32 | 2 | 216 | 21.2 | 0.886 |
| 34 | 33 | 1 | 218 | 25.1 | 0.886 |

TABLE 2

| Absorption layer [nm] | | | | | |
|---|---|---|---|---|---|
| Total | Absorption | Absorption | Phase | Relative | |
| thick- | film (1) | film (2) | difference | reflectance | Refractive |
| ness | Ru | Ir | [°] | [%] | index |
| 39 | 10 | 29 | 223 | 9.2 | 0.9 |
| 39 | 11 | 28 | 224 | 9.6 | 0.9 |
| 39 | 12 | 27 | 225 | 9.6 | 0.899 |
| 39 | 13 | 26 | 225 | 9.6 | 0.899 |
| 39 | 14 | 25 | 224 | 9.8 | 0.898 |
| 39 | 15 | 24 | 224 | 10.5 | 0.898 |
| 39 | 16 | 23 | 225 | 11.5 | 0.897 |
| 39 | 17 | 22 | 227 | 12.6 | 0.897 |
| 38 | 18 | 20 | 214 | 15.3 | 0.896 |
| 38 | 19 | 19 | 216 | 15.5 | 0.896 |
| 38 | 20 | 18 | 216 | 15.3 | 0.895 |
| 38 | 21 | 17 | 216 | 15.4 | 0.895 |
| 38 | 22 | 16 | 215 | 16.1 | 0.894 |
| 38 | 23 | 15 | 216 | 17.4 | 0.894 |
| 38 | 24 | 14 | 218 | 19.1 | 0.893 |
| 38 | 25 | 13 | 220 | 20.6 | 0.893 |
| 38 | 26 | 12 | 222 | 21.3 | 0.892 |
| 38 | 27 | 11 | 223 | 21.2 | 0.892 |
| 38 | 28 | 10 | 223 | 21.0 | 0.891 |
| 38 | 29 | 9 | 222 | 21.3 | 0.891 |
| 38 | 30 | 8 | 222 | 22.7 | 0.890 |
| 38 | 31 | 7 | 223 | 25.0 | 0.890 |
| 37 | 32 | 5 | 216 | 26.5 | 0.889 |
| 35 | 33 | 2 | 216 | 23.6 | 0.887 |
| 35 | 34 | 1 | 219 | 24.1 | 0.887 |

TABLE 3

| Absorption layer [nm] | | | | | |
|---|---|---|---|---|---|
| Total | Absorption | Absorption | Phase | Relative | |
| thick- | film (1) | film (2) | difference | reflectance | Refractive |
| ness | Ta | Pt | [°] | [%] | index |
| 45 | 15 | 30 | 215 | 3.4 | 0.913 |
| 45 | 16 | 29 | 210 | 3.7 | 0.914 |
| 45 | 17 | 28 | 208 | 4.0 | 0.916 |
| 45 | 18 | 27 | 208 | 4.2 | 0.917 |
| 45 | 19 | 26 | 209 | 4.2 | 0.919 |
| 45 | 20 | 25 | 208 | 4.0 | 0.920 |
| 46 | 22 | 24 | 225 | 2.2 | 0.922 |
| 46 | 23 | 23 | 217 | 2.2 | 0.924 |
| 46 | 24 | 22 | 212 | 2.4 | 0.925 |
| 47 | 26 | 21 | 226 | 0.9 | 0.927 |
| 47 | 27 | 20 | 228 | 0.8 | 0.929 |
| 47 | 28 | 19 | 225 | 0.5 | 0.930 |
| 47 | 29 | 18 | 209 | 0.3 | 0.931 |
| 53 | 36 | 17 | 228 | 1.3 | 0.936 |
| 53 | 37 | 16 | 216 | 1.2 | 0.937 |
| 53 | 38 | 15 | 207 | 1.4 | 0.938 |
| 54 | 40 | 14 | 209 | 0.5 | 0.940 |
| 54 | 41 | 13 | 218 | 0.4 | 0.941 |
| 54 | 42 | 12 | 219 | 0.2 | 0.942 |
| 59 | 48 | 11 | 212 | 3.2 | 0.944 |
| 59 | 49 | 10 | 212 | 2.5 | 0.945 |
| 59 | 50 | 9 | 205 | 1.8 | 0.947 |
| 59 | 50 | 9 | 205 | 1.8 | 0.947 |
| 60 | 51 | 9 | 215 | 0.4 | 0.947 |
| 67 | 61 | 6 | 235 | 1.2 | 0.951 |
| 67 | 62 | 5 | 213 | 2.9 | 0.952 |
| 67 | 63 | 4 | 219 | 2.1 | 0.953 |
| 67 | 64 | 3 | 216 | 1.2 | 0.954 |
| 67 | 65 | 2 | 216 | 1.2 | 0.955 |
| 73 | 72 | 1 | 221 | 0.6 | 0.956 |
| 80 | 80 | 0 | 214 | 0.6 | 0.957 |

As can be seen from Tables 1 to 3, the relative reflectance can be freely adjusted without greatly changing the phase difference, by making the total thickness of the absorption layer substantially constant and changing the thickness of each of the first absorption film and the second absorption film.

As can be seen from Table 3, when the refractive index of the absorption layer is 0.95 or less, the absorption layer can be formed thin with a total thickness of 60 nm or less, and thus the influence of shadowing can be reduced, and the efficiency can be improved in the etching process or the like at the time of manufacturing the reflective mask.

### (Antireflection Film)

When deep ultraviolet light (DUV light) having a wavelength of 190 nm to 260 nm is used in an inspection process, an antireflection film (not illustrated) configured to prevent reflection of DUV light having a wavelength of 190 nm to 260 nm is preferably laminated on or above the absorption layer 3.

The reflective mask is inspected whether the mask pattern formed on the absorption layer 3 has a defect. In the mask inspection, the presence or absence of a defect or the like is mainly determined based on optical data of reflected light of inspection light, and therefore, a light transmitted through the mask cannot be used as the inspection light, and DUV light is used. Therefore, it is preferable to provide, on or above the absorption layer 3, an antireflection film configured to prevent reflection of DUV light as the inspection light, for accurate inspection.

In order to play the above-described role, the antireflection film is preferably formed of a material having a lower refractive index of DUV light than the absorption layer 3. Examples of the constituent material of the antireflection film include a material containing Ta as a main component and one or more components selected from Hf, Ge, Si, B, N, H, and O in addition to Ta. Specific examples thereof include TaO, TaON, TaONH, TaHfO, TaHfON, TaBSiO, and TaBSiON.

The antireflection film can be formed in a desired thickness by using a known film forming method such as magnetron sputtering or ion beam sputtering.

### (Other Configurations)

In the reflective mask blank according to the present embodiment, a known functional film may be provided in the reflective mask blank in addition to the above-described films and layers.

For example, a back surface conductive film may be formed on or above a surface (back surface) of the substrate 1 opposite to the multilayer reflective film 2 in order to attract and fix the reflective mask blank 10 to a placement portion or the like of an electrostatic chuck.

The back surface conductive film preferably has a sheet resistance of 100 Ω/□ or less, and a known configuration can be applied. Examples of constituent materials of the back surface conductive film include Si, TiN, Mo, Cr, and TaSi. A thickness of the back surface conductive film may be, for example, 10 nm to 1,000 nm.

The back surface conductive film can be formed to have a desired thickness by using a known film forming method such as magnetron sputtering, ion beam sputtering, chemical vapor deposition (CVD), vacuum deposition, or electroplating.

### [Reflective Mask]

In the reflective mask according to the present embodiment, a mask pattern is formed on the absorption layer 3 of the reflective mask blank 10 according to the present embodiment.

In the method for manufacturing the reflective mask according to the present embodiment, lithography can be applied, and in the etching process, it is preferable to pass through the etching process as illustrated in FIGS. 2A to 2C described above. That is, the formation of the mask pattern on the reflective mask blank 10 preferably includes a step of subjecting the absorption layer 3 of the reflective mask blank 10 to a sputter etching treatment and then to a chemical dry etching treatment.

By manufacturing the reflective mask by using the reflective mask blank according to the present embodiment and applying such an etching process, it is possible to efficiently and accurately form a mask pattern on the reflective mask blank. The method for manufacturing the reflective mask according to the present embodiment is particularly useful for manufacturing a phase shift mask.

As described above, the following configurations are disclosed in the present description.

<1> A reflective mask blank for EUV lithography, the reflective mask blank including:
a substrate;
a multilayer reflective film configured to reflect EUV light; and
an absorption layer configured to absorb EUV light, in this order from a substrate side, in which
the absorption layer comprises a first absorption film and a second absorption film in this order from the substrate side,
the absorption layer has a refractive index for EUV light having a wavelength of 13.5 nm of 0.95 or less, and
the first absorption film is more easily chemically dry etched than the second absorption film.

<2> The reflective mask blank according to <1>, in which the second absorption film includes one or more metal elements selected from Group 9 elements to Group 13 elements.

<3> The reflective mask blank according to <2>, in which the one or more metal elements in the second absorption film are selected from a group consisting of cobalt (Co), rhodium (Rh), iridium (Ir), nickel (Ni), palladium (Pd), platinum (Pt), copper (Cu), silver (Ag), gold (Au), cadmium (Cd), and indium (In).

<4> The reflective mask blank according to any of <1> to <3>, in which the first absorption film includes one or more metal elements selected from Group 4 elements to Group 8 elements and Group 14 elements.

<5> The reflective mask blank according to <4>, in which the one or more metal elements in the first absorption film are selected from a group consisting of titanium (Ti), niobium (Nb), tantalum (Ta), chromium (Cr), molybdenum (Mo), tungsten (W), rhenium (Re), iron (Fe), ruthenium (Ru), osmium (Os), silicon (Si), germanium (Ge), and tin (Sn).

<6 The reflective mask blank according to any of <1> to <5>, in which the absorption layer has a total thickness of 60 nm or less.

<7> The reflective mask blank according to any of <1> to <6>, in which a phase difference between a reflected light from a surface of the multilayer reflective film and a reflected light from a surface of the absorption layer is 150° to 270° with respect to an incident light of EUV light having a wavelength of 13.5 nm at an incident angle of 6°.

<8> The reflective mask blank according to any of <1> to <7>, further including an antireflection film configured to prevent reflection of DUV light having a wavelength of 190 nm to 260 nm on or above the absorption layer.

<9> A reflective mask including:
the reflective mask blank according to any of <1> to <8>; and
a mask pattern formed on the absorption layer.

<10> A method for manufacturing the reflective mask according to <9>, the method including:
forming the mask pattern, in which
the formation of the mask pattern is performed by subjecting the absorption layer of the reflective mask blank to a sputtering etching treatment and then to a chemical dry etching treatment.

### EXAMPLES

Hereinafter, the present invention will be specifically described based on Examples, but the present invention is not limited to the following examples, and various modifications can be made without departing from the gist of the present invention.

### Example 1

### (Production of Reflective Mask Blank)

The reflective mask blank 10 having a film structure as illustrated in FIG. 1 was produced.

As the substrate 1 for film formation, an SiO₂—TiO₂ glass substrate (outer shape of 6-inch (152 mm) square, thickness of 6.3 mm, thermal expansion coefficient (20° C.) of 0.02× 10-7/° C., Young's modulus of 67 GPa, Poisson's ratio of 0.17, specific rigidity of 3.07×10⁷ m²/s²) was used. The Young's modulus was measured by an ultrasonic pulse method. A surface of the glass substrate was polished to have a surface roughness (RMS) of 0.15 nm or less and a smoothness (TIR) of 100 nm or less.

An Si film (thickness of 4.5 nm) and an Mo film (thickness of 2.3 nm) were formed on the surface of the substrate 1 by ion beam sputtering (Ar gas, gas pressure of 2.0×10⁻² Pa, 700 V), and the above as one cycle was repeated for 40 cycles to form an Mo/Si multilayer reflective film 2 having a total film thickness of 272 nm. The Si film was formed using a boron-doped Si target at a film formation rate of 0.077 nm/sec., and the Mo film was formed using an Mo target at a film formation rate of 0.064 nm/sec.

Further, an Rh film (thickness of 2.5 nm) was formed on the Mo/Si multilayer reflective film 2 by DC sputtering (Ar gas, gas pressure of 2.0×10⁻² Pa, input power density per target area of 3.7 W/cm², Rh target, film formation rate of 0.048 nm/sec), thereby forming a protective layer.

Next, the absorption layer 3 in which the first absorption film 3a and the second absorption film 3b were laminated was formed on the protective layer as follows.

First, the first absorption film 3a (thickness of 29 nm) of an Ru film was formed on the protective layer by DC magnetron sputtering (Ar gas, gas pressure of 4.0×10⁻¹ Pa, Ru target, input power density per target area of 5.0 W/cm², target-to-substrate distance of 45 mm, film formation rate of 6.2 nm/min).

Next, the second absorption film 3b (thickness of 6 nm) of a Pt film is laminated on the first absorption film 3a by DC magnetron sputtering (Ar gas, gas pressure of 4.0×10⁻¹ Pa, Pt target, input power density per target area of 5.0 W/cm², target-to-substrate distance of 45 mm, film formation rate of 12 nm/min) in the same manner as the first absorption film 3a, thereby forming the absorption layer 3 (total thickness of 35 nm) to obtain the reflective mask blank.

A mask pattern was formed on the reflective mask blank obtained by the above procedure, and the following etching process evaluation was performed. It is considered that the following mask pattern formation and etching process evaluation do not depend on the material of the substrate 1, the presence or absence and the material of the multilayer reflective film 2, the protective layer, and the buffer layer.

### (Mask Pattern Formation)

The reflective mask blank was set in a spin coater, and a photo resist (“ZPP 1,700”, manufactured by Nippon Zeon Co., Ltd.) was applied onto the second absorption film 3b of the reflective mask blank at a rotation speed of 500 rpm for 5 seconds, the rotation speed was increased to 2,500 rpm, and the photo resist was further applied for 30 seconds.

The treated sample was pre-baked by heating on a hot plate at 110° C. for 150 seconds.

Next, the treated sample was subjected to UV irradiation (wavelength of 365 nm, exposure time of 1.0 second, exposure amount of 200 mJ/cm²) using an exposure apparatus (“mask aligner MA8”, manufactured by Suss Microtec k.k..) to draw a mask pattern, and thereafter, development was performed using a developer (“NMD-W”, manufactured by TOKYO OHKA KOGYO CO., LTD.) for 60 seconds to remove an unnecessary photo resist.

The treated sample was heated on a hot plate at 130° C. for 3 minutes and post-baked to form a resist pattern.

### (Etching Process)

The sample on which the resist pattern was formed was placed on a sample table of an inductively coupled (ICP) plasma etching apparatus, and sputtering etching (gas of Cl₂ (4 sccm)/He (16 sccm), pressure of 3.0×10⁻¹ Pa, antenna power of 100 W, substrate power of 40 W, etching rate of Ru of 4.4 nm/min and Pt of 11.2 nm/min) was performed for 62 seconds.

Further, chemical dry etching (gas of Cl₂ (10 sccm)/O₂ (10 sccm), pressure of 3.0×10⁻¹ Pa, antenna power of 100 W, substrate power of 40 W, etching rate of Ru of 25.9 nm/min and Pt of 3.4 nm/min) was performed for 150 seconds.

### (Removal of Photoresist)

The etched sample was immersed in dimethylacetamide at 60° C. for 10 minutes or longer, and further immersed in dimethylacetamide at 25° C. for 3 minutes to remove an unnecessary photo resist including the resist pattern. The treated sample was immersed in acetone for 3 minutes, then immersed in isopropyl alcohol for 3 minutes, rinsed in ultrapure water, and then dried to obtain a reflective mask sample.

### Example 2

The thickness of the Ru film as the first absorption film in the production of the reflective mask blank in Example 1 was changed to 23 nm, and the thickness of the Pt film as the second absorption film was changed to 12 nm. The treatment time of the sputtering etching in the etching process was changed to 124 seconds, and the treatment time of the chemical dry etching was changed to 138 seconds. Except for the above, a reflective mask sample was produced in the same manner as in Example 1.

### Example 3

In the production steps of the reflective mask blank in Example 1, the first absorption film was not formed, and the thickness of the Pt film as the second absorption film was changed to 20 nm. In addition, the treatment time of the sputtering etching in the etching process was 207 seconds, and the chemical dry etching was not performed.

Except for the above, a reflective mask sample was produced in the same manner as in Example 1.

### [Evaluation]

Regarding the reflective mask samples of Examples 1 to 3, when the cross section of each sample after the etching process was observed with a field emission scanning electron microscope (FE-SEM; “SU-70”, manufactured by Hitachi High-Tech Corporation.), no residue or surface roughness was observed on the etching surface on the multilayer reflective film in Examples 1 and 2. In contrast, the surface roughness of the etching surface on the multilayer reflective film was significant in Example 3.

The results are shown in Table 4. In the column of the absorption layer in Table 4, the absorption film (1) refers to the first absorption film, and the absorption film (2) refers to the second absorption film.

TABLE 4

| Example | | 1 | 2 | 3 |
|---|---|---|---|---|
| Absorption | Total thickness [nm] | 35 | 35 | 20 |
| layer | Absorption film | 29 | 23 | — |
| | (1) Ru [nm] | | | |
| | Absorption film | 6 | 12 | 20 |
| | (2) Pt [nm] | | | |
| | Refractive index | 0.889 | 0.889 | 0.891 |

| | | | |
|---|---|---|---|
| Sputter etching [sec] | 62 | 124 | 207 |
| Chemical dry etching [sec] | 150 | 138 | — |
| Surface roughness on | Absence | Absence | Presence |
| etching surface | | | |

From the above, it can be said that the reflective mask having no surface roughness and no residue of the multilayer reflective film can be efficiently produced by constituting the absorption layer with the second absorption film and the first absorption film which is more easily chemically dry etched than the second absorption film.

Although the present invention has been described in detail with reference to specific embodiments, it is apparent to those skilled in the art that various changes and modifications can be made without departing from the spirit and scope of the present invention.

### REFERENCE SIGNS LIST

10: reflective mask blank
1: substrate
2: multilayer reflective film
3: absorption layer
3a: first absorption film
3b: second absorption film
4: resist pattern

What is claimed is:

1. A reflective mask blank for EUV lithography, the reflective mask blank comprising:
a substrate;
a multilayer reflective film configured to reflect EUV light; and
an absorption layer configured to absorb EUV light, in this order from a substrate side, wherein
the absorption layer comprises a first absorption film and a second absorption film in this order from the substrate side,
the absorption layer has a refractive index for EUV light having a wavelength of 13.5 nm of 0.95 or less, and
the first absorption film is more easily chemically dry etched than the second absorption film.

2. The reflective mask blank according to claim 1, wherein the second absorption film comprises one or more metal elements selected from Group 9 elements to Group 13 elements.

3. The reflective mask blank according to claim 2, wherein the one or more metal elements in the second absorption film are selected from a group consisting of cobalt (Co), rhodium (Rh), iridium (Ir), nickel (Ni), palladium (Pd), platinum (Pt), copper (Cu), silver (Ag), gold (Au), cadmium (Cd), and indium (In).

4. The reflective mask blank according to claim 1, wherein the first absorption film comprises one or more metal elements selected from Group 4 elements to Group 8 elements and Group 14 elements.

5. The reflective mask blank according to claim 4, wherein the one or more metal elements in the first absorption film are selected from a group consisting of titanium (Ti), niobium (Nb), tantalum (Ta), chromium (Cr), molybdenum (Mo), tungsten (W), rhenium (Re), iron (Fe), ruthenium (Ru), osmium (Os), silicon (Si), germanium (Ge), and tin (Sn).

6. The reflective mask blank according to claim 1, wherein the absorption layer has a total thickness of 60 nm or less.

7. The reflective mask blank according to claim 1, wherein a phase difference between a reflected light from a surface of the multilayer reflective film and a reflected light from a surface of the absorption layer is 150° to 270° with respect to an incident light of EUV light having a wavelength of 13.5 nm at an incident angle of 6°.

8. The reflective mask blank according to claim 1, further comprising an antireflection film configured to prevent reflection of DUV light having a wavelength of 190 nm to 260 nm on or above the absorption layer.

9. A reflective mask comprising:
the reflective mask blank according to claim 1; and
a mask pattern formed on the absorption layer.

10. A method for manufacturing the reflective mask according to claim 9, the method comprising:
forming the mask pattern, wherein
the formation of the mask pattern is performed by subjecting the absorption layer of the reflective mask blank to a sputtering etching treatment and then to a chemical dry etching treatment.
